(19) United States
(12) Patent Application Publication
(10) Pub. No.: US 2025/0339873 A1
(43) Pub. Date: Nov. 6, 2025

(54) HEATING APPARATUS, HEATING METHOD, AND COMPUTER-READABLE RECORDING MEDIUM

(71) Applicant: Tokyo Electron Limited, Tokyo (JP)

(72) Inventors: Kouichirou Tanaka, Koshi City, Kumamoto (JP); Yukinobu Otsuka, Koshi City, Kumamoto (JP); Yuichi Terashita, Koshi City, Kumamoto (JP)

(21) Appl. No.: 18/864,203

(22) PCT Filed: May 1, 2023
(86) PCT No.: PCT/JP2023/017040

§ 371 Date: Nov. 8, 2024

(30) Foreign Application Priority Data
May 13, 2022 (JP) 2022-079345

(51) Int. Cl. B05C 9/14; B05C 13/00; B05C 15/00

(52) U.S. Cl. CPC B05C 9/14; B05C 13/00; B05C 15/00

(57) ABSTRACT

A heating apparatus includes a processing vessel forming therein a processing space in which a substrate is accommodated; a hot plate having a placement surface on which the substrate is placed, and a heating device configured to heat the substrate; an adjusting mechanism configured to adjust a height of the substrate with respect to the hot plate; an exhaust device configured to evacuate the processing space; and a controller. The controller performs: starting a heating processing of the substrate by setting the height of the substrate with respect to the hot plate to a predetermined height; and setting, when the heating processing reaches a predetermined progress level, the height of the substrate with respect to the hot plate to be lower than the predetermined height to place the substrate on or close to the hot plate, and switching evacuation of the processing space from OFF to ON.

### TECHNICAL FIELD

The various aspects and embodiments described herein pertain generally to a heating apparatus, a heating method, and a computer-readable recording medium.

### BACKGROUND

A heating apparatus disclosed in Patent Document 1 is configured to heat, within a processing vessel, a substrate having a coating film formed thereon, and has a placement device provided in the processing vessel to place the substrate therein, and a heating device for heating the substrate placed in the placement device. Further, in Patent Document 1, the processing vessel has a cover forming a ceiling thereof, and this cover has an exhaust room formed between a top surface portion and a bottom surface portion thereof. An outer exhaust port communicating with the exhaust room is formed in a peripheral portion of the bottom surface portion of the cover. A central exhaust port is formed in a central portion of the bottom surface portion of the cover. One end of a central exhaust line provided so as to penetrate the exhaust room is connected to the central exhaust port.

### PRIOR ART DOCUMENT

Patent Document 1: Japanese Patent Laid-open Publication No. 2021-00923

### DISCLOSURE OF THE INVENTION

### Problems to be Solved by the Invention

Exemplary embodiments provide a technique capable of suppressing a substrate from having a defect that might be caused by a substance generated in a processing space during heating, without impairing uniformity of a coating film within a surface of the substrate after being subjected to a heating processing.

### Means for Solving the Problems

In an exemplary embodiment, a heating apparatus configured to heat a substrate on which a coating film is formed includes a processing vessel forming therein a processing space in which the substrate is accommodated; a hot plate having a placement surface on which the substrate accommodated in the processing space is placed, and a heating device configured to heat the substrate; an adjusting mechanism configured to adjust a height of the substrate with respect to the hot plate; an exhaust device configured to evacuate the processing space; and a controller. The controller performs: starting a heating processing of the substrate by setting the height of the substrate with respect to the hot plate to a predetermined height that is away from the hot plate by a preset distance; and setting, when the heating processing reaches a predetermined progress level, the height of the substrate with respect to the hot plate to be lower than the predetermined height to place the substrate on or close to the hot plate, and switching evacuation of the processing space from OFF to ON.

### Effect of the Invention

According to the exemplary embodiment, it is possible suppress the substrate from having the defect that might be caused by the substance generated in the processing space during the heating, without impairing the uniformity of the coating film within the surface of the substrate after being subjected to the heating processing.

### BRIEF DESCRIPTION OF THE DRAWINGS

FIG. 1 is an explanatory diagram schematically illustrating a configuration of a heating apparatus according to an exemplary embodiment when viewed from the side.

FIG. 2A and FIG. 2B are diagrams illustrating a state of the heating apparatus in individual processes of a wafer processing according to the present exemplary embodiment.

FIG. 3A and FIG. 3B are diagrams illustrating the state of the heating apparatus in individual processes of the wafer processing according to the present exemplary embodiment.

FIG. 4 is a diagram illustrating a temperature history of a wafer W in a heating processing included in the wafer processing according to the present exemplary embodiment.

FIG. 5 is a diagram illustrating an evacuation scheme of a processing space in another example of the wafer processing according to the present exemplary embodiment.

FIG. 6 is a diagram illustrating the state of the processing space in a process of ending the heating processing in yet another example of the wafer processing according to the present exemplary embodiment.

FIG. 7A to FIG. 7C are explanatory diagrams for describing an effect of yet another example of the wafer processing according to the present exemplary embodiment.

FIG. 8A and FIG. 8B are explanatory diagrams for describing an effect of yet another example of the wafer processing according to the present exemplary embodiment.

FIG. 9A to FIG. 9C are diagrams illustrating a height of a cover member with respect to a bottom member in individual processes in still yet another example of the wafer processing according to the present exemplary embodiment.

FIG. 10 is an explanatory diagram illustrating data for use in determining whether or not the heating processing has progressed to a preset extent.

### DETAILED DESCRIPTION

In a manufacturing process for a semiconductor device, etc., various types of processing liquids, such as a processing liquid for forming a SOC film to be used as a hard mask, are coated on a surface of a substrate such as a semiconductor wafer (hereinafter, simply referred to as “wafer”). After the coating of these processing liquids, that is, after the formation of a coating film, there is performed a heating processing of heating the substrate in a processing vessel of a heating apparatus.

Further, in the heating apparatus, the inside of the processing vessel is evacuated for the purpose of collecting a defect-causing substance generated inside the processing vessel during the heating. The defect-causing substance is a substance that adheres to the substrate, causing a defect. Even if, however, the evacuation is performed as stated above, the defect-causing substance may not be completely collected. In addition, if an evacuation amount from the inside of the processing vessel is increased or an evacuation time is set to be long, the thickness of the coating film may become non-uniform within the surface of the substrate, although the defect-causing substance can be collected in a large quantity.

In view of the foregoing, the present disclosure provides a technique capable of suppressing the substrate from having a defect that might be caused by a substance generated in the processing vessel (specifically, in a processing space formed by the processing vessel) during the heating, without impairing the uniformity of the coating film within the surface of the substrate after being subjected to the heating processing.

Hereinafter, a heating apparatus and a heating method according to an exemplary embodiment will be described with reference to the accompanying drawings. In the preset specification and the drawings, parts having substantially the same functions and configurations will be assigned same reference numerals, and redundant descriptions thereof will be omitted.

### Heating Apparatus

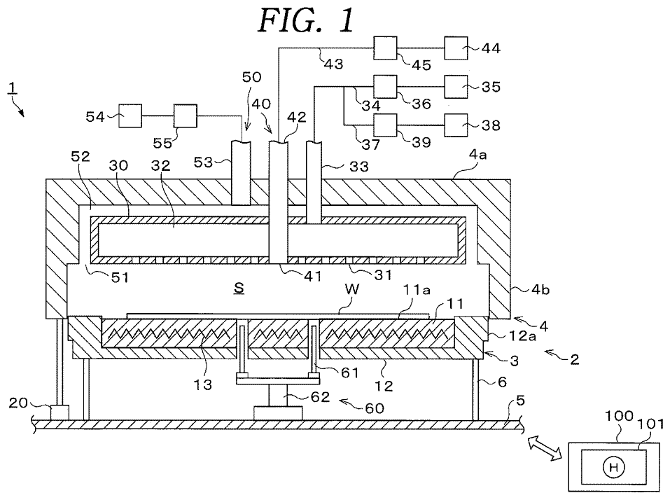

FIG. 1 is an explanatory diagram schematically illustrating a configuration of a heating apparatus according to the present exemplary embodiment, when viewed from the side.

As depicted in FIG. 1, a heating apparatus 1 has a processing vessel 2 forming a processing space S in which a wafer W as a substrate is accommodated therein. This processing vessel 2 has a bottom member 3 having a hot plate 11, and a cover member 4 including a ceiling portion 4a facing a placement surface 11a (to be described later) of the bottom member 3. The bottom member 3 and the cover member 4 forms the processing space S therebetween. In addition, the processing vessel 2 is provided in a non-illustrated housing.

The bottom member 3 is supported on a base 5 of the non-illustrated housing with a supporting member 6 therebetween. The bottom member 3 is equipped with a supporting table 12 formed as a flat cylindrical body having a recessed portion at an inner side than a peripheral portion 12a thereof. The hot plate 11 is provided in the recessed portion of the supporting table 12.

A top surface 11a of the hot plate 11 is a placement surface on which the wafer W is placed. A plurality of gap pins (not shown) configured to support a bottom surface of the wafer W may be provided on the top surface 11a (hereinafter, referred to as placement surface 11a) of the hot plate 11.

Further, a heater 13 as a heating device configured to heat the wafer W is provided inside the hot plate 11. The heater 13 is capable of heating the wafer W by heating the placement surface 11a. Specifically, the heater 13 may heat the placement surface 11a to heat the wafer W placed on the placement surface 11a, and, also, to heat the wafer W located at a position spaced from the placement surface 11a. The heater 13 is controlled by a controller 100 described later.

The ceiling portion 4a of the cover member 4 is formed to have a circular plate shape with a diameter larger than that of the bottom member 3.

In addition, the cover member 4 has a sidewall portion 4b that encloses a space between the bottom member 3 and the ceiling portion 4a to form the processing space S. The sidewall portion 4b is formed in an annular shape when viewed from the top.

This cover member 4 is moved up and down by an elevating mechanism 20. The elevating mechanism 20 has a driving source such as a motor configured to generate a driving force for moving the cover member 4 up and down, that is, a driving force for adjusting the height of the cover member 4 with respect to the bottom member 3, and is provided at, for example, the base 5. This elevating mechanism 20 is controlled by the controller 100 to be described later. The elevating mechanism 20 can form the processing space S by lowering the cover member 4. Also, the elevating mechanism 20 can open the processing space S by raising the cover member 4. In addition, the elevating mechanism 20 can change the volume of the processing space S by moving the cover member 4 up and down, that is, by adjusting the height of the cover member 4 with respect to the bottom member 3.

In this way, the elevating mechanism 20 constitutes an adjusting mechanism configured to adjust the height of the cover member 4 with respect to the bottom member 3, and also constitutes a changing device configured to change the volume of the processing space S.

In addition, a shower head 30 is provided at the ceiling portion 4a of the cover member 4.

The shower head 30 is configured to supply a gas containing oxygen, i.e., an oxygen-containing gas downwards from the ceiling portion 4a. The oxygen-containing gas supplied by the shower head 30 is, by way of non-limiting example, dry air.

Also, the shower head 30 is configured to supply an inert gas not containing oxygen downwards from the ceiling portion 4a. The inert gas supplied by the shower head 30 is, for example, a nitrogen gas.

The shower head 30 has a plurality of discharge holes 31 and a gas distribution space 32.

Each of the discharge holes 31 is formed in a bottom surface of the shower head 30. The discharge holes 31 are arranged in an approximately uniform manner in a central portion of the bottom surface of the shower head 30 other than where an exhaust opening 41 to be described later is provided. The plurality of discharge holes 31 include first discharge holes positioned above a peripheral portion of the wafer W on the hot plate 11, and second discharge holes positioned above a central portion of the wafer W on the hot plate 11.

The gas distribution space 32 distributes the oxygen-containing gas or inert gas introduced into the shower head 30 into the respective discharge holes 31.

An inlet line 33 for introducing the oxygen-containing gas or inert gas into the shower head 30 is connected to the shower head 30.

The inlet line 33 is connected via a supply line 34 to a gas source 35 configured to store therein the oxygen-containing gas. The supply line 34 is provided with a supply equipment group 36 including a flow rate control valve and an opening/closing valve for controlling a flow of the oxygen-containing gas.

Further, the gas source 38 configured to store therein the inert gas is also connected to the inlet line 33 via a supply line 37. The supply line 37 is provided with a supply equipment group 39 including a flow rate control valve and an opening/closing valve for controlling a flow of the inert gas.

The supply equipment groups 36 and 39 are controlled by the controller 100 to be described later.

In the heating apparatus 1, the shower head 30, the inlet line 33, the supply line 37, and the supply equipment group 39 constitute a gas supply configured to supply the inert gas into the processing space S, and the shower head 30, the inlet line 33, the supply line 34, and the supply equipment group 36 constitute another gas supply configured to supply the oxygen-containing gas into the processing space S.

Further, the heating apparatus 1 is provided with a central exhaust device 40 and a peripheral exhaust device 50. The central exhaust device 40 and the peripheral exhaust device 50 constitute an exhaust device configured to evacuate the processing space S.

The central exhaust device 40 evacuates the processing space S from a position above the placement surface 11a and corresponding to the central position (the center position in the shown example) of the wafer W on the placement surface 11a. The central exhaust device 40 has an exhaust port 41. The exhaust port 41 is provided at a central position (the center position in the shown example) in the bottom surface of the shower head 30 and is opened downwards. The central exhaust device 40 evacuates the processing space S through this exhaust port 41.

In addition, the central exhaust device 40 has a central exhaust path 42 formed to extend upwards from the exhaust port 41. An exhaust device 44 such as a vacuum pump is connected to the central exhaust path 42 via an exhaust line 43. The exhaust line 43 is provided with an exhaust equipment group 45 having a valve for adjusting an evacuation amount, or the like. The exhaust device 44 and the exhaust equipment group 45 are controlled by the controller 100 to be described later.

The peripheral exhaust device 50 evacuates the processing space S from a position above the placement surface 11a and corresponding to the peripheral position (a position slightly outside a circumferential edge of the wafer W in the shown example) of the wafer W on the placement surface 11a. The peripheral exhaust device 50 has an exhaust port 51. The exhaust port 51 is opened downwards from a bottom surface of the ceiling portion 4a so as to surround an outer periphery of the shower head 30. The exhaust port 51 may be formed by arranging a plurality of exhaust holes along the outer periphery of the shower head 30. The peripheral exhaust device 50 evacuates the processing space S through the exhaust port 51.

In addition, the peripheral exhaust device 50 has a peripheral exhaust path 52 leading to the exhaust port 51. An exhaust device 54 such as a vacuum pump is connected to the peripheral exhaust path 52 via an exhaust line 53. An exhaust equipment group 55 having a valve for adjusting an evacuation amount, etc., is provided in the exhaust line 53. The exhaust device 54 and the exhaust equipment group 55 are controlled by the controller 100 to be described later.

In addition, the ceiling portion 4a is configured to be heated. For example, the ceiling portion 4a has a non-illustrated heater embedded therein to heat the ceiling portion 4a. This heater is controlled by the controller 100 to be described later, and the ceiling portion 4a (specifically, the shower head 30, for example) is adjusted to a set temperature.

In addition, in the heating apparatus 1, an elevating mechanism 60 configured to move the wafer W up and down is provided below the bottom member 3. The elevating mechanism 60 is provided with an elevating pin 61 as a delivery member for delivering the wafer W to/from a non-illustrated transfer mechanism provided outside the processing vessel 2, and this elevating pin 61 is configured to penetrate the supporting table 12 and the hot plate 11. For example, at least three elevating pins 61 are arranged at an equal distance therebetween in a circumferential direction of the hot plate 11.

The elevating pins 61 are configured to be raised and lowered by the elevating mechanism 62 and to protrude upwards from the hot plate 11 when they are raised. The elevating mechanism 62 has a driving source such as a motor configured to generate a driving force for raising and lowering the elevating pins 61, and is provided on, for example, the base 5. By raising and lowering the elevating pins 61, the height of the wafer W supported by the elevating pins 61 with respect to the hot plate 11 can be adjusted. This elevating mechanism 62 is controlled by the controller 100 to be described below.

In this way, the elevating mechanism 60 constitutes an adjustment mechanism that adjusts the height of the wafer W with respect to the hot plate 11.

The above-described heating apparatus 1 includes the controller 100. The controller 100 is, for example, a computer equipped with a processor such as a CPU and a memory, and has a storage 101. The storage 101 stores programs including instructions for controlling various operations of the heating apparatus 1 to be described later, for example. The programs may be recorded in a computer-readable recording medium H and installed from the recording medium H into the controller 100. The recording medium H may be transitory or non-transitory. In addition, some or all of the programs may be implemented by dedicated hardware (circuit board).

### Example 1 of Wafer Processing

Now, an example of a wafer processing including a heating processing performed by using the heating apparatus 1 according to the present exemplary embodiment will be described.

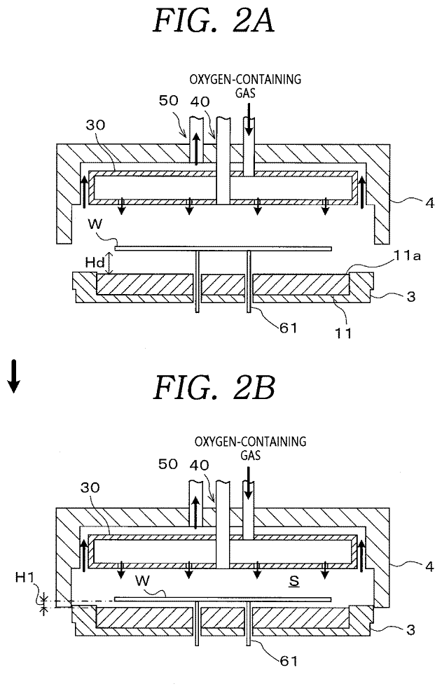

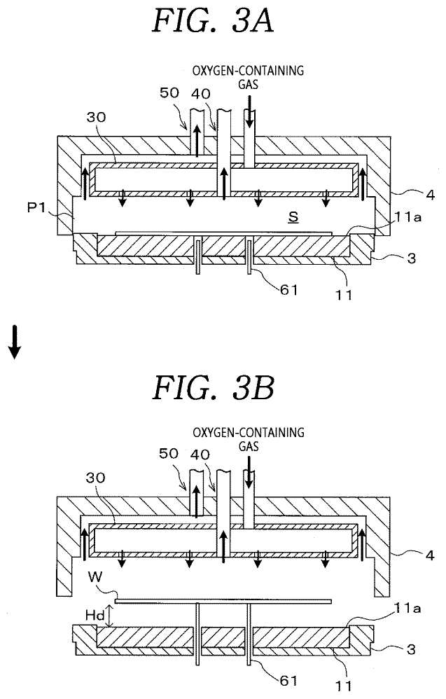

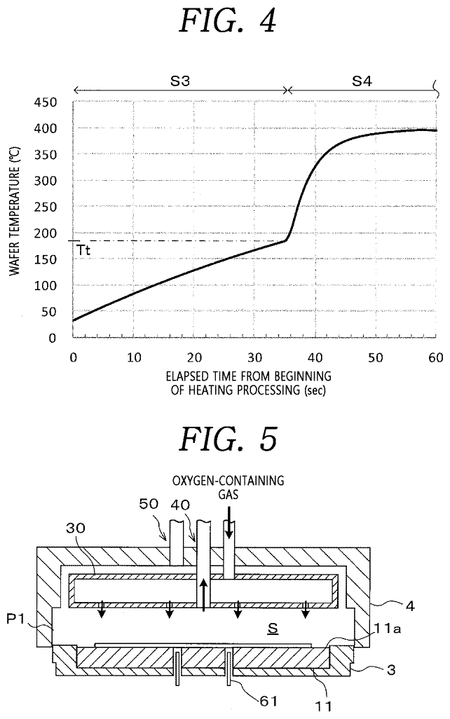

FIG. 2A to FIG. 3B are diagrams each showing a state of the heating apparatus 1 in respective processes of the wafer processing according to the present exemplary embodiment. FIG. 4 is a diagram showing a temperature history of the wafer W during the heating processing included in the wafer processing according to the present exemplary embodiment.

Further, the whole wafer processing according to the present exemplary embodiment exemplified below is performed under the control of the controller 100.

### (Process S1: Carry-in of Wafer W)

First, the wafer W is carried into the heating apparatus 1.

Specifically, after the cover member 4 is raised, the wafer W having the SOC film as the coating film formed thereon is moved to above the hot plate 11 by the non-illustrated transfer mechanism. Thereafter, the elevating pins 61 are raised, and the wafer W is handed over to the elevating pins 61 as shown in FIG. 2A. At this time, the height of the wafer W with respect to the hot plate 11 is raised up to a delivery height Hd. The delivery height Hd is, for example, 30 mm to 50 mm.

At this time, the evacuation by the central exhaust device 40 is turned OFF. On the other hand, the evacuation by the peripheral exhaust device 50 is always turned ON during the wafer processing.

Furthermore, at this time, the heater 13 is controlled such that the temperature of the placement surface 11a of the hot plate 11 is in the range of, e.g., 200° C. to 450° C. In addition, during the wafer processing, the heater 13 is controlled to maintain the temperature of the placement surface 11a of the hot plate 11 constant, for example. Also, the non-illustrated heater for the ceiling portion 4a is controlled to maintain the temperature of the ceiling portion 4a (specifically, the shower head 30) constant at a set temperature during the wafer processing, for example.

### (Process S2: Start of Heating Processing)

Subsequently, the height of the wafer W with respect to the hot plate 11 becomes a predetermined height, that is, a first height H1 which is apart from the hot plate 11 by a predetermined distance, and the heating processing is started.

Specifically, the cover member 4 is lowered, so the processing space S is formed, as shown in FIG. 2B.

Also, concurrently with or after the lowering of the cover member 4, the elevating pins 61 are lowered, and the height of the wafer W with respect to the hot plate 11 becomes the first height H1 that is lower than the delivery height Hd. Once the processing space S is formed as the height of the wafer W relative to the hot plate 11 becomes the first height H1 in this way, the heating processing is started. Here, the first height H1 is, for example, 2 mm to 10 mm, and is preset to be stored in the storage 101.

Additionally, during the heating processing, the height of the cover member 4 with respect to the bottom member 3, i.e., the volume of the processing space S is constant.

### (Process S3: Heating at First Height H1)

Next, the wafer W is heated at the first height H1, and the evacuation by the peripheral exhaust device 50 is performed, so that the defect-causing substance generated in the processing space S during the heating is collected.

Specifically, the height of the wafer W with respect to the hot plate 11 is maintained at the first height H1, and, also, the oxygen-containing gas is supplied from the shower head 30 into the processing space S.

Further, the evacuation by the peripheral exhaust device 50 is performed, and the defect-causing substance in the processing space S, such as the defect-causing substance generated from the SOC film during the heating, are collected.

Moreover, the discharge of the oxygen-containing gas from the shower head 30 may be performed before the start of the heating processing.

The process S3 is performed until the degree of progress of the heating processing reaches a preset level. Specifically, the process S3 is performed until the temperature of the wafer W reaches a predetermined temperature Tt that is slightly lower than a temperature at which a crosslinking reaction between the SOC film and the oxygen is initiated, as shown in FIG. 4.

The determination upon whether the heating processing has progressed to the preset degree, that is, whether the temperature of the wafer W has reached the predetermined temperature Tt is performed based on, for example, whether the time elapsed after the height of the wafer W with respect to the hot plate 11 becomes the first height H1 exceeds a preset time T1. If the elapsed time exceeds the preset time T1, the controller 100 makes a determination that the heating processing has progressed to the preset degree, that is, that the predetermined temperature Tt has been reached. The ‘preset time T1’ used for this determination varies depending on the type of the SOC film, and is set in advance based on a user input via an input device such as a non-illustrated keyboard or touch panel to be stored in the storage 101, for example.

### (Process S4: Lowering of Wafer W)

Then, after the heating processing has progressed to the preset degree, the wafer W is lowered.

Specifically, after the heating processing has progressed to the predetermined degree, the elevating pins 61 are lowered, and the wafer W is placed on the placement surface 11a of the hot plate 11.

### (Process S5: Heating in Placed State)

Next, the wafer W is heated in the state in which the wafer W is placed on the hot plate 11, and the evacuation by the peripheral exhaust device 50 and the evacuation by the central exhaust device 40 are performed, so that the defect-causing substance generated in the processing space S during the heating are collected.

To elaborate, as shown in FIG. 3A, the state in which the wafer W is placed on the hot plate 11 is maintained, and, also, the oxygen-containing gas is supplied from the shower head 30 into the processing space S. When the wafer W heated by the hot plate 11 exceeds a preset temperature, a material in the SOC film on the wafer W undergoes a crosslinking reaction with the oxygen in the processing space S, etc., due to the heat. The SOC film is hardened, that is, becomes etching resistant as a result of the crosslinking reaction taking place therein.

In addition, the exhaust equipment group 45 is controlled, so that the evacuation by the central exhaust device 40 is switched from OFF to ON, and both the evacuation by the peripheral exhaust device 50 and the evacuation by the central exhaust device 40 are performed. As a result, the defect-causing substance in the processing space S, such as the defect-causing substance generated from the SOC film during the heating, is collected.

This process S5 is performed until a preset time T2 elapses after the wafer W is placed on the hot plate 11.

The preset time T2 (that is, a heating time in the state where the wafer W is placed on the hot plate 11) is, for example, 30 seconds to 120 seconds, and the preset time T1 (that is, a heating time at the first height H1) is 0.5 times to 1.5 times the preset time T2.

The timing at which the evacuation by the central exhaust device 40 is switched from OFF to ON is, as a specific example, immediately after the start of the heating in the process S5 (that is, immediately after the wafer W is placed on the hot plate 11). Alternatively, the timing may be upon the lapse of a preset time T3 after the heating of the process S5 is begun (that is, after the wafer W is placed on the hot plate 11). The reason for this will be described later. The preset time T3 is, for example, between 2 seconds to 10 seconds inclusive.

### (Process S6: Completion of Heating Processing)

Upon the completion of the process S5, the elevating pins 61 are raised to separate the wafer W from the placement surface 11a, the cover member 4 is raised to open the processing space S, and the heating processing is completed.

Specifically, upon the completion of the process S5, the raising of the elevating pins 61 and the raising of the cover member 4 are performed at the same time while carrying on the supply of the oxygen-containing gas from the shower head 30 into the processing space S and keeping ON the evacuation by the central exhaust device 40 and the evacuation by the peripheral exhaust device 50. As a result, as shown in FIG. 3B, the wafer W is raised to the delivery height Hd, and the processing space S is opened.

### (Process S7: Carry-out of Wafer W)

Thereafter, the wafer W is carried out of the heating apparatus 1.

Specifically, the elevating pins 61 are lowered, and the wafer W is handed over to the non-illustrated transfer mechanism and moved from above the hot plate 11 by the transfer mechanism.

In this way, the wafer processing according to the present exemplary embodiment is completed.

As a wafer processing different from the present exemplary embodiment, a wafer processing according to comparative examples 1 and 2 below is assumed.

### Comparative Example 1

The heating of the wafer W at the first height H1 is not performed, and only the heating of the wafer W in the state where it is placed on the hot plate 11 is performed. During the heating, both the evacuation by the central exhaust device 40 and the evacuation by the peripheral exhaust device 50 are turned ON from the very beginning.

### Comparative Example 2

The heating of the wafer W at the first height H1 is not performed, and only the heating of the wafer W in the state where it is placed on the hot plate 11 is performed. During the heating, for the first 10 seconds to 20 seconds, the evacuation by the central exhaust device 40 is turned OFF, and only the evacuation by the peripheral exhaust device 50 is turned ON. Thereafter, for about 50 seconds, both the evacuation by the central exhaust device 40 and the evacuation by the peripheral exhaust device 50 are turned ON.

However, through repeated experiments, the inventors of the present application have found that Comparative Examples 1 and 2 have the following problems. That is, in the wafer processing according to Comparative Example 1, although no defect is found on the surface of the wafer W after the wafer processing, the thickness of the SOC film after the wafer processing is found to be thickened at the central portion of the wafer W. In addition, in the wafer processing according to Comparative Example 2, depending on the type of the SOC film, the defect-causing substance in the processing space S cannot be sufficiently collected, resulting in the defect on the surface of the wafer W after the wafer processing. Even if the evacuation time is lengthened, there still arise cases where the defect cannot be reduced sufficiently.

This is deemed to be because as follows. In the SOC film of the type concerned, when the heating of the wafer W at the first height H1 is not performed, if the evacuation by the central exhaust device 40 is not performed during a period when the temperature of the wafer W changes greatly, such as immediately after the start of the heating processing and immediately after the wafer W is placed on the hot plate 11, there is generated the defect-causing substance that cannot be collected even by the evacuation through the central exhaust device 40 performed afterwards.

Meanwhile, in the wafer processing according to the present exemplary embodiment, the wafer W is placed on the hot plate 11 after being subjected to the heating at the first height H1. Accordingly, the temperature variation of the wafer W immediately after the start of the heating processing and the temperature variation of the wafer W immediately after it is placed on the hot plate 11 are relatively gentle. Therefore, in the wafer processing according to the present exemplary embodiment, it is possible to suppress the generation of the defect-causing substance P that is difficult to collect, which might be generated during a period when the temperature variation of the wafer W is sharp.

In addition, in a heating processing for the wafer W on which the SOC film is formed, fluidity of the SOC film is the highest in an initial stage, so a film thickness is likely to be affected by the evacuation. Meanwhile, in the wafer processing according to the present exemplary embodiment, in the process of heating the wafer W at the first height H1, which corresponds to the initial stage of the heating processing, the evacuation by the central exhaust device 40 is in the OFF state. Therefore, the increase of the thickness of the SOC film at the central portion of the wafer W as a result of performing the central evacuation during the heating processing can be suppressed.

Furthermore, in the example of the wafer processing according to the present exemplary embodiment described above, the height of the wafer W with respect to the hot plate 11 in the heating of the process S5 is equal to the height at which the wafer is placed on the hot plate 11. However, the height of the wafer W in the heating of the process S5 is not particularly limited thereto as long as the wafer W is placed closer to the hot plate 11 than at the first height H1. The same applies to the following examples.

### Main Effects of Present Exemplary Embodiment

As described above, the wafer processing according to the present exemplary embodiment includes the process (a) of starting the heating processing of the wafer W by setting the height of the wafer W with respect to the hot plate 11 to the first height H1 which is away from the hot plate 11 by the predetermined distance; and the process of, when the heating processing has progressed to the preset degree, setting the height of the wafer W with respect to the hot plate 11 to be lower than the first height H1 so that the wafer W is placed on or close to the hot plate 11, and, also, switching the evacuation of the processing space S from OFF to ON. For this reason, the temperature variation of the wafer W is relatively gentle throughout the entire period of the heating processing. Therefore, it is possible to suppress the generation of the defect-causing substance P that is difficult to collect, which might occur during a period when the temperature variation of the wafer W is sharp. In addition, in the wafer processing according to the present exemplary embodiment, it is not until the heating processing progresses to the preset degree, that is, the fluidity of the coating film on the wafer W decreases that the evacuation of the processing space S (specifically, the evacuation by the central exhaust device 40) for improving the collection efficiency of the defect-causing substance in the processing space S is turned ON. Therefore, the occurrence of in-plane non-uniformity of the film thickness due to the evacuation of the processing space S (specifically, the evacuation by the central exhaust device 40) can be suppressed.

Thus, according to the present exemplary embodiment, the occurrence of the defect on the wafer W that might be caused by the substance generated in the processing space S during the heating can be suppressed without damaging the uniformity of the coating film within the surface of the wafer W after being subjected to the heating processing.

As stated above, the timing at which the evacuation by the central exhaust device 40 is switched from OFF into ON may be upon the lapse of the preset time T3 after the wafer W is placed on the hot plate 11. This is because, depending on the type of the coating film or the heating time at the first height H1, with the heating at the first height H1 alone, the fluidity of the coating film may not be sufficiently reduced to the extent that it is not affected by the evacuation by the central exhaust device 40.

### Example 2 of Wafer Processing

FIG. 5 is a diagram illustrating evacuation scheme of the processing space S in another example of the wafer processing according to the present exemplary embodiment.

In the above-described example, in the process S6 of ending the heating processing, the cover member 4 is raised to open the processing space S while the evacuation by the central exhaust device 40 and the evacuation by the peripheral exhaust device 50 are kept ON. Instead of this, in the process S6 of ending the heating processing, while keeping ON the evacuation by the central exhaust device 40, the evacuation by the peripheral exhaust device 50 may be turned OFF, and then, after the lapse of the preset time T2, the cover member 4 may be raised to open the processing space S, as shown in FIG. 5. Accordingly, when the processing space S is opened, the defect-causing substance can be suppressed from leaking out of the processing vessel 2 from a gap between the bottom member 3 and the cover member 4.

### Example 3 of Wafer Processing

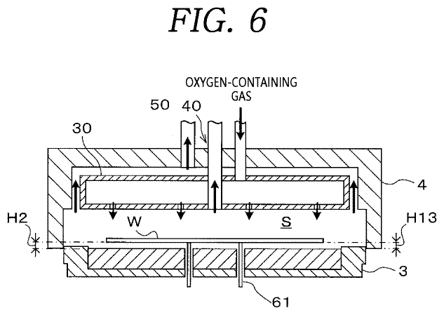

FIG. 6 is a diagram illustrating a state of the processing space S in the process S6 of ending the heating processing in yet another example of the wafer processing according to the present exemplary embodiment.

In Example 1, etc., of the wafer processing described above, in the process S6 of ending the heating processing, while keeping ON the evacuation by the central exhaust device 40 and the evacuation by the peripheral exhaust device 50, the elevating pins 61 (that is, the wafer W) and the cover member 4 are raised at the same time, so that the wafer W is raised to the delivery height Hd and the processing space S is opened. Instead of this, in the process S6 of ending the heating processing, only the raising of the elevating pins 61 may be performed while keeping ON the evacuation by the central exhaust device 40 and the evacuation by the peripheral exhaust device 50, so that the height of the wafer W with respect to the hot plate 11 may become a second height H2, and the processing space S may remain closed, as shown in FIG. 6. Then, upon the lapse of the preset time T3, the elevating pins 61 and the cover member 4 may be raised again simultaneously, so that the wafer W may be raised to the delivery height Hd and the processing space S may be opened.

Here, the first height H1 and the second height H2 may be equal to or different from each other.

The second height H2 is set in advance to be stored in the storage 101, like the first height H1, for example.

Further, the second height H2 may be calculated and decided in advance by the controller 100 as will be stated below, and may be stored in the storage 101. That is, the controller 100 may acquire a detection result of a bending amount of the wafer W as a processing target from a non-illustrated external detection device, and the second height H2 may be calculated and decided in advance based on the detection result to be stored in the storage 101. Here, the external detection device is, for example, a commonly known device configured to image the wafer W from the side and detect the bending amount of the wafer W from the imaging result.

For example, the second height H2 is calculated and decided from the detection result of the bending amount of the wafer W as the processing target by the controller 100, as follows.

That is, a sum of an acquired bending amount Wp of the wafer W and a default value H2₀ of the second height H2 stored in the storage 101 is calculated by the controller 100, and the result is determined as the actual second height H2 (=Wp+H2₀). Accordingly, a height H3 of the peripheral portion of the wafer W with respect to a lower end of a peripheral portion of the cover member 4 becomes constant regardless of the bending amount of the wafer W.

If the height H3 of the peripheral portion of the wafer W with respect to the lower end of the peripheral portion of the cover member 4 varies, an airflow that flows to the surface of the wafer W through a space under the peripheral portion of the cover member 4 also changes when the elevating pins 61 are re-raised and the cover member 4 is raised simultaneously to open the processing space S. Specifically, when the re-raising of the elevating pins 61 and the raising of the cover member 4 are performed simultaneously to open the processing space S, the airflow that flows to the surface of the wafer W may decrease when the height H3 is large, whereas the airflow that flows to the surface of the wafer W may increase when the height H3 is small. Therefore, by maintaining constant the height H3 of the peripheral portion of the wafer W with respect to the lower end of the peripheral portion of the cover member 4 regardless of the bending amount the wafer W, the airflow that flows to the surface of the wafer W when the processing space S is opened as described above also becomes approximately constant. As a result, the influence of the bending of the wafer W on the result of the heating processing can be suppressed.

In addition, in the present example, the evacuation scheme of the processing space S in the process S6 of ending the heating processing may be the same as that of Example 6 of the wafer processing described above. That is, in the process S6 of ending the heating processing, of the evacuation by the central exhaust device 40 and the evacuation by the peripheral exhaust device 50, only the evacuation by the peripheral exhaust device 50 may be turned OFF before the cover member 4 is raised, and, then, the cover member 4 may be raised to open the processing space S after the preset time T3 passes by.

In addition, when performing Examples 1 to 3 of the wafer processing as described above, the supply line 37, the gas source 38, and the supply equipment group 39 used to supply the inert gas into the processing space S may be omitted from the heating apparatus 1.

### Example 4 of Wafer Processing

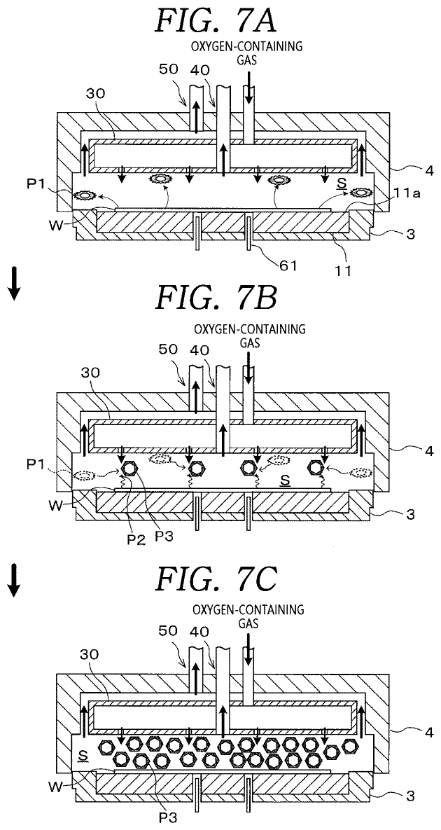

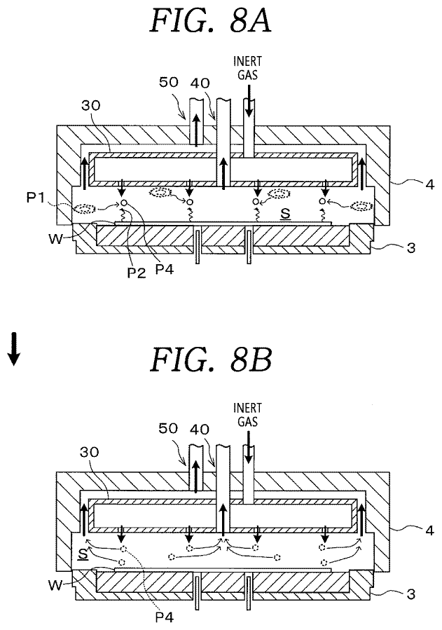

FIG. 7A to FIG. 8B are explanatory diagrams illustrating an effect of yet another example of the wafer processing according to the present exemplary embodiment. In the above-described examples, during the heating processing, the gas supplied into the processing space S is the oxygen-containing gas, and the switching into the inert gas is not performed.

Meanwhile, in the present example, the gas supplied to the processing space S is switched from the oxygen-containing gas to the inert gas during the heating processing, so that the oxygen-containing gas in the processing space S is replaced with the inert gas. That is, in the present example, the heating in the oxygen-containing gas atmosphere is switched to the heating in the low-oxygen concentration atmosphere (specifically, the heating in the inert gas atmosphere) during the heating processing.

The timing at which the gas supplied into the processing space S is switched from the oxygen-containing gas to the inert gas is, for example, during the heating of the wafer W in the state that it is placed on the hot plate 11 in the process S5.

To elaborate, the timing is, for example, during the heating in the process S5, when the crosslinking reaction due to the reaction between the SOC film on the wafer W and the oxygen has progressed to a preset degree, more specifically, when a temperature Ts equal to or higher than a temperature at which the crosslinking reaction in the SOC film is completed has been reached.

Determination upon whether the crosslinking reaction due to the reaction between the SOC film and the oxygen has progressed to the preset degree, that is, determination upon whether the temperature of the wafer W has reached the preset temperature Ts is performed based on, for example, whether an elapsed time after the wafer W is placed on the hot plate 11 exceeds a predetermined time T11. If the elapsed time exceeds the predetermined time T11, the controller 100 makes a determination that the preset progress degree has been achieved, that is, that the predetermined temperature Ts has been reached. The ‘predetermined time T11’ used for this determination varies depending on the type of the SOC film, and is set in advance based on, for example, a user input through an input device such as a non-illustrated keyboard or touch panel and stored in the storage 101.

In the case of performing the heating under the inert gas atmosphere at the latter stage of the heating processing as in the present example, when the heating processing is terminated, the supply of the inert gas from the shower head 30 into the processing space S is stopped before the cover member 4 is raised, that is, before the processing space S is opened.

In a period including immediately after the placement of the wafer W on the hot plate 11, a relatively large diameter defect-causing substance P1 may scatter from the SOC film, as shown in FIG. 7A, due to a rapid temperature variation or the like. This scattering of the defect-causing substance P1 subsides as the heating processing progresses. Unlike in the present example, however, if the switching to the inert gas is not performed, the aforementioned defect-causing substance P1 may later combine with a fine particle P2 caused by a material vaporized from the SOC film on the wafer W and the oxygen in the processing space S to become another defect-causing substance P3 having a large mass, as illustrated in FIG. 7B, as the heating processing progresses. This defect-causing substance P3 is not only large in mass but is also generated in a large quantity. Therefore, through the evacuation by the central exhaust device 40 and the evacuation by the peripheral exhaust device 50, the defect-causing substance P3 may not be completely collected, and, as shown in FIG. 7C, the defect-causing substance P3 may fill the processing space S at the end of the heating processing and remain attached to the entire surface of the wafer W after the wafer processing is ended.

Meanwhile, in the wafer processing according to the present example, after the crosslinking reaction in the SOC film due to the oxygen progresses to the preset degree (specifically, upon the completion of the crosslinking reaction), the gas supplied to the processing space S is switched from the oxygen-containing gas to the inert gas. Therefore, even if the relatively large diameter defect-causing substance P1 described above scatters during the period including immediately after the wafer W is placed on the hot plate 11, this defect-causing substance P1 does not combine with the aforementioned fine particle P2 and the oxygen in the processing space S, as shown in FIG. 8A. Therefore, the defect-causing substance P1 does not turn into the defect-causing substance P3 having the large mass (see FIG. 7B). Instead, the defect-causing substance P1 is partially volatilized by the heat to be reduced in size (in FIG. 8A, P4 denotes a reduced defect-causing substance). The reduced defect-causing substance P4 can be easily collected through the evacuation by the central exhaust device 40 and the evacuation by the peripheral exhaust device 50, as shown in FIG. 8B. Therefore, the processing space S can be suppressed from being filled with the defect-causing substance P3 (see FIG. 2B) or other defect-causing substances at the end of the heating processing, so that the defect-causing substances can be suppressed from remaining attached to the entire surface of the wafer W after the completion of the wafer processing.

When the timing at which the gas supplied into the processing space S is switched from the oxygen-containing gas to the inert gas is the timing described above, the evacuation by the central exhaust device 40 may be switched from OFF into ON at the same time as the gas is switched.

Furthermore, the timing at which the gas supplied into the processing space S is switched from the oxygen-containing gas to the inert gas, that is, the timing at which the processing space S is replaced with the inert gas may be when the heating of the process S5 is begun, that is, when the wafer W is lowered to be placed on the hot plate 11 in the process S4.

### Example 5 of Wafer Processing

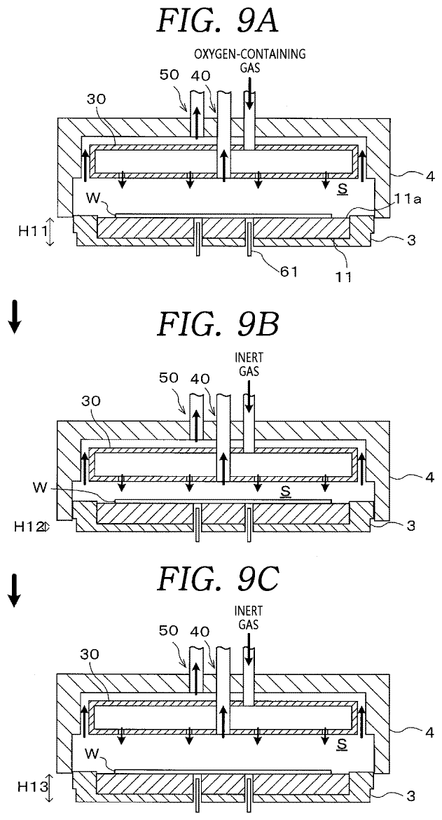

FIG. 9A to FIG. 9C are diagrams showing the height of the cover member 4 with respect to the bottom member 3 in individual processes of still yet another example of the wafer processing according to the present exemplary embodiment.

In the above-described examples, the height of the cover member 4 with respect to the bottom member 3, that is, the volume of the processing space S is maintained constant. Instead, however, the volume of the processing space S may be reduced in the process of replacing the oxygen-containing gas in the processing space S with the inert gas (hereinafter, referred to as replacement process), as compared to that in the heating process under the oxygen-containing gas atmosphere. In this case, in the heating process under the inert gas atmosphere, the volume of the processing space S may be set to be larger than that in the replacement process.

To elaborate, the heating process in the oxygen-containing gas atmosphere may be performed in the state where the height of the cover member 4 with respect to the bottom member 3 is set to a first height H11, as shown in FIG. 9A, and the replacement process may be performed in the state where the height of the cover member 4 with respect to the bottom member 3 is set to a second height H12 lower than the first height H12, as shown in FIG. 9B. Also, in this case, the heating process in the inert gas atmosphere may be performed in the state where the height of the cover member 4 with respect to the bottom member 3 is set to a third height H13 higher than the second height H12. The third height H13 may be equal to or different from the first height H11.

As in the present example, by reducing the volume of the processing space S in the replacement process, the time required to replace the atmosphere within the processing space S with the inert gas can be shortened. As a result, the generation of the aforementioned defect-causing substance P3 with the larger mass can be suppressed.

In addition, in the heating process in the inert gas atmosphere, by increasing the volume of the processing space S as described above, that is, by increasing the height of the cover member 4 with respect to the bottom member 3, the airflow directly above the wafer W can be made more uniform within the surface of the wafer W. Furthermore, it is possible to suppress the defect-causing substance from adhering to the cover member 4 (specifically, the shower head 30) and contaminating it.

In the heating process in the inert gas atmosphere, when the volume of the processing space S is set to be larger than that in the replacement process as described above, a supply flow rate of the inert gas into the processing space S may be set to be high in the replacement process and set to be relatively low in the heating process in the inert gas atmosphere. As a result, the consumption of the inert gas in the entire heating processing can be reduced while shortening the time required to replace the atmosphere in the processing space S with the inert gas in the replacement process.

### Modification Examples

In Example 1, etc., of the wafer processing described above, the determination upon whether the heating processing has progressed to the preset degree, that is, the determination upon whether the temperature of the wafer W has reached the predetermined temperature Tt is performed based on the preset time T1 on the basis of the user input through the input device such as a non-illustrated keyboard or touch panel.

However, the way to determine whether the heating processing has progressed to the preset degree, that is, the way to determine whether the temperature of the wafer W has reached the predetermined temperature Tt is not limited thereto.

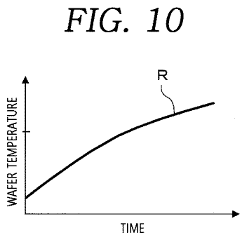

By way of example, data D1 representing a relationship R such as that shown in FIG. 10 is stored in the storage 101 in advance. The relationship R is a relationship between the temperature of the wafer W and the heating time obtained when the wafer W is heated with the hot plate 11 set to a current set temperature and the height of the wafer W with respect to the hot plate 11 set to the preset first height H1. Further, the predetermined temperature (i.e., the target temperature reached by the heating at the first height H1) Tt is received from the user through the input device such as the non-illustrated keyboard or touch panel and stored in the storage 101 in advance. Then, the determination upon whether the temperature of the wafer W has reached the predetermined temperature Tt may be performed based on the data D1 stored in the storage 101. Specifically, the controller 100 may calculate and determine a time T21 required for the temperature of the wafer W to reach the predetermined temperature Tt based on the data D1 stored in the storage 101 and the predetermined temperature Tt, and the determination upon whether the temperature of the wafer W has reached the predetermined temperature Tt may be carried out based on a determination upon whether the elapsed time after the height of the wafer W with respect to the hot plate 11 becomes the first height H1 exceeds the time T21.

The time T21 required for the temperature of the wafer W to reach the predetermined temperature Tt, which is determined as information for use in determining whether the temperature of the wafer W has reached the predetermined temperature Tt, may be outputted externally via an external output device such as a non-illustrated display (for example, a liquid crystal display).

In addition, data D2 in which the relationship R between the temperature of the wafer W and the heating time obtained when the wafer W is heated with the height of the wafer W with respect to the hot plate 11 set to the first height H1 is indicated for each temperature of the hot plate 11 and each height of the wafer W with respect to the hot plate 11 may be previously stored in the storage 101. Then, the determination upon whether the temperature of the wafer W has reached the predetermined temperature Tt may be performed based on the data D2 stored in the storage 101.

By way of example, set values of the current temperature of the hot plate 11, the predetermined temperature Tt and the first height H1 are received from the user through the input device such as the non-illustrated keyboard or touch panel, and are stored in the storage 101 in advance. Further, the controller 100 calculates and determines the time T21 required for the temperature of the wafer W to reach the predetermined temperature Tt based on these information and the data D2. Then, the controller 100 makes a determination upon whether the temperature of the wafer W has reached the predetermined temperature Tt based on the determination upon whether the elapsed time after the height of the wafer W with respect to the hot plate 11 becomes the first height H1 exceeds the time T21.

In addition, the relationship R between the temperature of the wafer W and the heating time obtained when the wafer W is heated with the height of the wafer W with respect to the hot plate 11 set to the first height H1 is affected not only by the set temperature of the hot plate 11 and the height of the wafer W with respect to the hot plate 11 but also by the set temperature of the cover member 4 (specifically, the shower head 30). Therefore, data D3 in which the relationship R is indicated for each temperature of the hot plate 11, each height of the wafer W with respect to the hot plate 11, and each temperature of the cover member 4 may be previously stored in the storage 101. Then, the determination upon whether the temperature of the wafer W has reached the predetermined temperature Tt may be carried out based on the data D3 stored in the storage 101.

By way of example, set values of the temperature of the cover member 4, the temperature of the hot plate 11, the predetermined temperature Tt and the first height H1 are received from the user through the input device such as the non-illustrated keyboard or touch panel, and are stored in the storage 101 in advance. Further, the controller 100 calculates and determines the time T21 required for the temperature of the wafer W to reach the predetermined temperature Tt based on these information and data D2. Then, the controller 100 makes a determination on whether the temperature of the wafer W has reached the predetermined temperature Tt based on the determination on whether the elapsed time after the height of the wafer W with respect to the hot plate 11 becomes the first height H1 exceeds the time T21.

In the example using the data D2 or the data D3, the same as in the example using the data D1, the time T21 required for the temperature of the wafer W to reach the predetermined temperature Tt, which is determined as information for use in determining whether the temperature of the wafer W has reached the predetermined temperature Tt, may be outputted externally via the external output device such as the non-illustrated display (for example, the liquid crystal display).

In addition, based on the data D2, a candidate for information used to determine whether the temperature of the wafer W has reached the predetermined temperature Tt may be decided.

For example, set values of the temperature of the hot plate 11 and the predetermined temperature Tt as well as a tolerance range as the time T21 required for the temperature of the wafer W to reach the predetermined temperature Tt are received from the user through the input device such as the non-illustrated keyboard or touch panel, and are stored in the storage 101 in advance. Further, based on these information and data D2, a candidate for a combination of the time T21 and the first height H1 is determined by the controller 100. The determined candidate may be outputted externally through the external output device such as the non-illustrated display (for example, the liquid crystal display).

Likewise, based on the data D3, a candidate for information used to determine whether the temperature of the wafer W has reached the predetermined temperature Tt may be decided.

By way of example, set values of the temperature of the cover member 4, the temperature of the hot plate 11, and the predetermined temperature Tt as well as the tolerance range as the time T21 required for the temperature of the wafer W to reach the predetermined temperature Tt are received from the user through the input device such as the non-illustrated keyboard or touch panel, and are stored in the storage 101 in advance. In addition, the candidate for the combination of the time T21 and the first height H1 is determined based on these information and data D3 by the controller 100. The determined candidate may be outputted externally through the external output device such as the non-illustrated display (for example, the liquid crystal display).

Moreover, the candidate for the combination of the time T21 and the height H1 determined based on the data D2 or the data D3 may be narrowed down as follows based on the detection result of the bending amount of the wafer W as the processing target.

That is, when the shape of the wafer W is of a protruding shape (a shape with its center protruding upwards) when viewed from the side and the bending amount of the wafer W is large, a distance from the hot plate 11 is short at the peripheral portion of the wafer W, so that the heating amount is large, and, as a result, there is a concern that the in-plane uniformity of the film thickness may be deteriorated. Therefore, when the wafer W has the protruding shape when viewed from the side and the bending amount is 500 um or more, the candidate for the combination of the time T21 and the first height H1 may be narrowed down by the controller 100 to only those in which the first height H1 is 3 mm or more.

Further, the detection result of the bending amount of the wafer W as the processing target is acquired from a non-illustrated external detection device, for example. Also, information other than the bending amount of the wafer W, which is necessary to narrow down the candidate for the combination, is previously stored in the storage 101, for example.

Additionally, the first height H1 may be adjusted as follows based on the detection result of the bending amount of the wafer W as the processing target. That is, a default value of the first height H1 is set. When the wafer W has the protruding shape when viewed from the side and the bending amount is 500 μm or more, a value larger than the default value is set as the first height H1, and in other cases, the default value may be set as the first height H1.

In the above description, although the height of the cover member 4 with respect to the bottom member 3 is adjusted by raising and lowering the cover member 4, it may be also possible to adjust the height by raising and lowering the cover member 4.

Further, in the above description, although the height of the wafer W with respect to the hot plate 11 is adjusted by raising and lowering the wafer W, it may be also possible to adjust the height by raising and lowering the hot plate 11.

In the above description, the SOC film is used as an example of the coating film. The technique of the present disclosure, however, may also be applicable to other types of coating films.

It should be noted that the exemplary embodiments described herein are illustrative in all aspects and are not anyway limiting. The above-described exemplary embodiments can be omitted, replaced, or modified in various ways without departing from the scope of claims, appendix and the gist thereof. Unless contradictory, other configurations may be adopted, and the disclosures in the various exemplary embodiments can be combined appropriately. For example, the constituent elements of the above-described exemplary embodiment can be combined in various ways within a range that does not impair the above-described effects. In addition, the technique according to the present disclosure can exhibit other effects that are apparent to those skilled in the art from the description of the present specification, along with or instead of the above-described effects.

Additionally, the following configurations also fall within the technical scope of the present disclosure.

### Appended 1

A heating apparatus configured to heat a substrate on which a coating film is formed, the heating apparatus including:
a processing vessel forming therein a processing space in which the substrate is accommodated;
a hot plate having a placement surface on which the substrate accommodated in the processing space is placed, and a heating device configured to heat the substrate;
an adjusting mechanism configured to adjust a height of the substrate with respect to the hot plate;
an exhaust device configured to evacuate the processing space; and
a controller,
wherein the controller performs:
starting a heating processing of the substrate by setting the height of the substrate with respect to the hot plate to a predetermined height that is away from the hot plate by a preset distance; and
setting, when the heating processing reaches a predetermined progress level, the height of the substrate with respect to the hot plate to be lower than the predetermined height to place the substrate on or close to the hot plate, and switching evacuation of the processing space from OFF to ON.

### Appended 2

The heating apparatus described in Appended 1,
wherein the exhaust device includes:
a central exhaust device configured to evacuate the processing space from a position above the placement surface and corresponding to a central position of the substrate on the placement surface; and
a peripheral exhaust device configured to evacuate the processing space from a position above the placement surface and corresponding to a peripheral position of the substrate on the placement surface, and
the controller performs:
keeping OFF evacuation by the central exhaust device in the starting of the heating processing of the substrate and switching from OFF to ON in the setting of the height of the substrate and the switching of the evacuation of the processing space; and
keeping ON evacuation by the peripheral exhaust device from the starting of the heating processing of the substrate.

### Appended 3

The heating apparatus described in Appended 2,
wherein the processing vessel includes:
a bottom member including the hot plate; and
a cover member including a ceiling wall facing the placement surface, and forming the processing space between the bottom member and the cover member,
the heating apparatus further includes an additional adjusting mechanism configured to adjust a height of the cover member with respect to the bottom member, and
the controller performs turning, at an end of the heating processing, OFF the evacuation by the peripheral exhaust device while keeping ON the evacuation by the central exhaust device, and then, upon a lapse of a preset time, increasing the height of the cover member with respect to the bottom member to open the processing space.

### Appended 4

The heating apparatus described in any one of Appended 1 to 3,
wherein the controller makes, at a current set temperature of the hot plate, a determination on whether the heating processing reaches the predetermined progress level or decides information on the determination based on data indicating a relationship between a substrate temperature and a heating time obtained when the height of the substrate with respect to the hot plate is the predetermined height.

### Appended 5

The heating apparatus described in any one of claims 1 to 3,
wherein the controller performs at least one of deciding the predetermined height, making a determination on whether the heating processing reaches the predetermined progress level, deciding information on the determination, or deciding a candidate for the information, based on data indicating a relationship between a substrate temperature and a heating time for each temperature of the hot plate and each height of the substrate with respect to the hot plate.

### Appended 6

The heating apparatus described in Appended 4, further including:
a storage storing the data.

### Appended 7

The heating apparatus described in Appended 5, further including:
a storage storing the data.

### Appended 8

The heating apparatus described in any one of Appended 1 to 7, further including:
a gas supply configured to supply an inert gas into the processing space,
wherein the controller performs replacing an oxygen-containing gas in the processing space with the inert gas during the heating processing.

### Appended 9

The heating apparatus described in Appended 8,
wherein the controller performs replacing the oxygen-containing gas in the processing space with the inert gas during the setting of the height of the substrate and the switching of the evacuation of the processing space.

### Appended 10

A heating method of heating a substrate on which a coating film is formed, the heating method including:
starting a heating processing of the substrate by setting a height of the substrate with respect to a hot plate to a predetermined height which is away from the hot plate by a predetermined distance, the hot plate having a placement surface on which the substrate accommodated in a processing space is to be placed; and
setting the height of the substrate with respect to hot plate to be lower than the predetermined height when the heating processing reaches a predetermined progress level to place the substrate on or close to the hot plate, and switching evacuation of the processing space from OFF to ON.

### Appended 11

A computer-readable recording medium having stored thereon computer-executable instructions that, in response to execution, cause a heating apparatus to perform a heating method of heating a substrate on which a coating film is formed,
wherein the heating method includes:
starting a heating processing of the substrate by setting a height of the substrate with respect to a hot plate to a predetermined height which is away from the hot plate by a predetermined distance, the hot plate having a placement surface on which the substrate accommodated in a processing space is to be placed; and
setting the height of the substrate with respect to hot plate to be lower than the predetermined height when the heating processing reaches a predetermined progress level to place the substrate on or close to the hot plate, and switching evacuation of the processing space from OFF to ON.

### EXPLANATION OF CODES

1: Heating apparatus
2: Processing vessel
11: Hot plate
11a: Placement surface
13: Heater
20: Elevating mechanism
40: Central exhaust device
50: Peripheral exhaust device
60: Elevating mechanism
100: Controller
S: Processing space
W: Wafer

1. A heating apparatus configured to heat a substrate on which a coating film is formed, the heating apparatus comprising:
a processing vessel forming therein a processing space in which the substrate is accommodated;
a hot plate having a placement surface on which the substrate accommodated in the processing space is placed, and a heating device configured to heat the substrate;
an adjusting mechanism configured to adjust a height of the substrate with respect to the hot plate;
an exhaust device configured to evacuate the processing space; and
a controller,
wherein the controller performs:
starting a heating processing of the substrate by setting the height of the substrate with respect to the hot plate to a predetermined height that is away from the hot plate by a preset distance; and
setting, when the heating processing reaches a predetermined progress level, the height of the substrate with respect to the hot plate to be lower than the predetermined height to place the substrate on or close to the hot plate, and switching evacuation of the processing space from OFF to ON.

2. The heating apparatus of claim 1,
wherein the exhaust device comprises:
a central exhaust device configured to evacuate the processing space from a position above the placement surface and corresponding to a central position of the substrate on the placement surface; and
a peripheral exhaust device configured to evacuate the processing space from a position above the placement surface and corresponding to a peripheral position of the substrate on the placement surface, and
the controller performs:
keeping OFF evacuation by the central exhaust device in the starting of the heating processing of the substrate and switching from OFF to ON in the setting of the height of the substrate and the switching of the evacuation of the processing space; and
keeping ON evacuation by the peripheral exhaust device from the starting of the heating processing of the substrate.

3. The heating apparatus of claim 2,
wherein the processing vessel comprises:
a bottom member including the hot plate; and
a cover member including a ceiling wall facing the placement surface, and forming the processing space between the bottom member and the cover member,
the heating apparatus further comprises an additional adjusting mechanism configured to adjust a height of the cover member with respect to the bottom member, and
the controller performs turning, at an end of the heating processing, OFF the evacuation by the peripheral exhaust device while keeping ON the evacuation by the central exhaust device, and then, upon a lapse of a preset time, increasing the height of the cover member with respect to the bottom member to open the processing space.

4. The heating apparatus of claim 1,
wherein the controller makes, at a current set temperature of the hot plate, a determination on whether the heating processing reaches the predetermined progress level or decides information on the determination based on data indicating a relationship between a substrate temperature and a heating time obtained when the height of the substrate with respect to the hot plate is the predetermined height.

5. The heating apparatus of claim 1,
wherein the controller performs at least one of deciding the predetermined height, making a determination on whether the heating processing reaches the predetermined progress level, deciding information on the determination, or deciding a candidate for the information, based on data indicating a relationship between a substrate temperature and a heating time for each temperature of the hot plate and each height of the substrate with respect to the hot plate.

6. The heating apparatus of claim 4, further comprising:
a storage storing the data.

7. The heating apparatus of claim 5, further comprising:
a storage storing the data.

8. The heating apparatus of claim 1, further comprising:
a gas supply configured to supply an inert gas into the processing space, wherein the controller performs replacing an oxygen-containing gas in the processing space with the inert gas during the heating processing.

9. The heating apparatus of claim 8,
wherein the controller performs replacing the oxygen-containing gas in the processing space with the inert gas during the setting of the height of the substrate and the switching of the evacuation of the processing space.

10. A heating method of heating a substrate on which a coating film is formed, the heating method comprising:
starting a heating processing of the substrate by setting a height of the substrate with respect to a hot plate to a predetermined height which is away from the hot plate by a predetermined distance, the hot plate having a placement surface on which the substrate accommodated in a processing space is to be placed; and
setting the height of the substrate with respect to hot plate to be lower than the predetermined height when the heating processing reaches a predetermined progress level to place the substrate on or close to the hot plate, and switching evacuation of the processing space from OFF to ON.

11. A computer-readable recording medium having stored thereon computer-executable instructions that, in response to execution, cause a heating apparatus to perform a heating method of heating a substrate on which a coating film is formed,
wherein the heating method comprises:
starting a heating processing of the substrate by setting a height of the substrate with respect to a hot plate to a predetermined height which is away from the hot plate by a predetermined distance, the hot plate having a placement surface on which the substrate accommodated in a processing space is to be placed; and
setting the height of the substrate with respect to hot plate to be lower than the predetermined height when the heating processing reaches a predetermined progress level to place the substrate on or close to the hot plate, and switching evacuation of the processing space from OFF to ON.
